(19) United States
(12) Patent Application Publication
(10) Pub. No.: US 2026/0165142 A1
(43) Pub. Date: Jun. 11, 2026

(54) HIGHLY-EFFECTIVE ULTRATHIN SPUTTER ABLE AND TAMPER-RESISTANT SHIELDS WITH METAL-REFRACTORY ALLOY STACKS

(71) Applicants: Applied Materials, Inc., Santa Clara, CA (US); The Florida International University Board of Trustees, Miami, FL (US)

(72) Inventors: Ghaleb Saleh Ghaleb AL-DUHNI, Miami, FL (US); John Leonidas VOLAKIS, Miami, FL (US); Mohammad Mohtasim Hamid PIAL, Miami, FL (US); Markondeyaraj PULUGURTHA, Miami, FL (US); Kunal Ghosh, Bengaluru (IN); Mudit Sunilkumar KHASGIWALA, Milpitas, CA (US)

(73) Assignees: Applied Materials, Inc., Santa Clara, CA (US); The Florida International University Board of Trustees, Miami, FL (US)

(21) Appl. No.: 19/343,689

(22) Filed: Sep. 29, 2025

Related U.S. Application Data
(60) Provisional application No. 63/730,852, filed on Dec. 11, 2024.

(51) Int. Cl. H01L 23/552; C23C 14/06; C23C 14/14; C23C 14/34; G06F 30/20; H01L 21/56

(52) U.S. Cl. CPC H10W 42/20; C23C 14/0629; C23C 14/14; C23C 14/34; G06F 30/20; H10W 74/01

(57) ABSTRACT

A method may include forming, on a semiconductor device, a first layer may include a first material configured to prevent transmission of electromagnetic radiation (EMR) through at least the first layer. The method may include forming, on the first layer, a second layer may include a nano amorphous material configured to prevent transmission EMR through at least the first layer and the second layer. The method may include forming, on the second layer, a third layer may include a third material configured to prevent transmission of EMR through at least the first layer, the second layer, and the third layer, where the first material, the nano amorphous material, and the third material are configured to maximize the internal reflection of the EMR between the first, second, and third layers.

### CROSS-REFERENCES TO RELATED APPLICATIONS

This application claims the benefit of priority to U.S. Patent Application No. 63/730,852 filed Dec. 11, 2024, the contents of which are hereby incorporated by reference in their entirety for all purposes.

### TECHNICAL FIELD

The present technology relates to semiconductor devices and the manufacturing thereof. Specifically, the present technology relates to tamper-resistant shielding structures for semiconductor device.

### BACKGROUND

Semiconductor devices may rely on electrical signals both for power and communication. The signals that are used and/or generated by one device may interfere with another device. Additionally, outside signals may interfere or tamper with the device. To mitigate the effects of unwanted signals (e.g., electromagnetic radiation), shielding structures are commonly used to protect these devices. Common shielding structures may be relatively thick in order to provide the requisite protection from unwanted signals. This thickness, however, may enable an attacker to remove the shielding structure (or a portion thereof) and reverse engineer the protected device. Thus, a shielding structure is needed that can protect semiconductor devices from unwanted signals and physical tampering.

### BRIEF SUMMARY

A method may include forming, on a semiconductor device, a first layer may include a first material configured to prevent transmission of electromagnetic radiation (EMR) through at least the first layer. The method may include forming, on the first layer, a second layer may include a nano amorphous material configured to prevent transmission EMR through at least the first layer and the second layer. The method may include forming, on the second layer, a third layer may include a third material configured to prevent transmission of EMR through at least the first layer, the second layer, and the third layer, where the first material, the nano amorphous material, and the third material are configured to maximize the internal reflection of the EMR between the first, second, and third layers.

In some embodiments, a total thickness of the first, second, and third layers is within a range of 3.5 micrometers and 5 micrometers, inclusive. The first, second, and third layers may be formed via a sputtering process. The first and third layers may include aluminum. The second layer may include cadmium zinc telluride (CZT). At least one of the first layer, the second layer, or the third layer may include a nano amorphous alloy. The semiconductor device may be a component of a semiconductor package. The shielding structure may be configured to reduce the transmission of the first frequency, the second frequency, and the third frequency by 40 db to 80 db, inclusive. The first layer may be formed to a thickness of between 250 nm and 400 nm, inclusive.

A semiconductor package may include a substrate. The package may include a semiconductor device disposed on the substrate. The package may include an interconnect layer electrically connected to the semiconductor device. The package may include an electromagnetic radiation (EMR) shielding structure disposed on the semiconductor device, the interconnect layer, or some combination thereof configured to shield the semiconductor device from tampering. The EMR shielding structure may include: a first aluminum layer, a CZT layer, and a second aluminum layer.

In some embodiments, the EMR shielding structure may include a thickness in a range of 2.5 to 3.5 micrometers, inclusive. The EMR shielding structure may be configured to shield EMR frequencies in a range of 50 mhz to 2000 mhz, inclusive. The EMR shielding structure may include a set of aluminum layers and a set of CZT layers, and the total number of layers may be 9. The CZT layer may include at least one of tantalum, zirconium, or some combination thereof. The shielding structure may include a cobalt iron alloy.

A method of generating a manufacturing plan for a shielding structure] may include receiving, by a computing system, one or more parameters defining shielding effectiveness (SE) of the shielding structure, manufacturing parameters, or some combination thereof. The method may include determining, by the computing system, two or more materials according to the one or more parameters. The method may include generating, by the computing system, a model shielding structure may include the two or more materials and according to the one or more parameters, where the model shielding structure may include two or more layers, where adjacent layers may include different materials of the two or more materials. The method may include generating, by the computing system, SE data by simulating the operation of a semiconductor device may include the model shielding structure. If the SE data is within the one or more parameters, the method may include generating, by the computing system, a manufacturing plan for the EMR shielding structure indicating the two or more layers and the two or more materials of the model shielding structure.

In some embodiments, at least one of the two or more materials may include a nano amorphous alloy. The EMR shielding structure may include a thickness in a range of 2.5 to 3.5 micrometers, inclusive. The model EMR shielding structure may be simulated on a semiconductor package.

### BRIEF DESCRIPTION OF THE DRAWINGS

FIG. 1 illustrates a flowchart of a method for manufacturing a tamper-resistant shielding structure, according to certain embodiments.

FIGS. 2A-2D illustrate a tamper resistant shielding structure, according to certain embodiments.

FIG. 3 illustrates a graph of the shield effectiveness of a 9-layer shielding structure, according to certain embodiments.

FIG. 4 illustrates a semiconductor device with component-level shielding structures, according to certain embodiments.

FIG. 5 illustrates a semiconductor device with a package-level shielding structure, according to certain embodiments.

FIG. 6 illustrates a flowchart of a method for generating a manufacturing plan for a shielding structure, according to certain embodiments.

FIG. 7 illustrates an exemplary computer system, in which various embodiments may be implemented.

### DETAILED DESCRIPTION

Electronic systems such as semiconductor devices rely on diverse computing, communication, sensing, and power conversion components. However, these components can may involuntarily produce electromagnetic interference (EMI) and disrupt signals, which contribute to severe design constraints and performance limitations. With a range of devices getting more advanced, ensuring electromagnetic compatibility (EMC) has now become a critical design consideration.

EMI comes from a variety of sources such switch mode power supplies (e.g., high-power inverters in electric vehicles and DC-DC converters, and from switch-mode power supplies), operation of various devices (e.g., integrated circuits, SoCs, etc.) within a semiconductor package, external sources (e.g., bad actors, nearby devices, etc.), and many other sources. For example, noise from components such as switches and inductors may create issues in power delivery networks (PDN) by operating at or near a harmonic frequency of that used by the PDN. Some computing systems have relatively high clock frequencies and thus create higher frequency noise. For example, metal-based films and coatings utilizing somewhat common materials such as aluminum, cobalt zirconium telluride (CZT), and other such materials may be utilized to mitigate the effects of high-frequency EMI (e.g., >1 GHZ). Protection EMI from low-frequency magnetic fields may require special ferromagnetic materials like nickel-iron (NiFe) or Mumetal. Thus, creating a shielding structure that is effective across a broad spectrum of EMI poses difficulties when selecting a single material.

Multilayered (i.e., multi-material) shielding structures ma exhibit improved performance across certain spectra. For example, copper and/or polyethylene terephthalate (PET) films may exhibit significant isolation capability across relevant spectra of EMI. In another example, a Cu/NiFe stack-up with a thickness of 13 micrometer (μm) may have a 28 dB shielding effectiveness (SE) at 10 MHz (but weak SE at low frequencies). In yet another example, styrene-acrylonitrile (SAN) copolymer with graphite (Gr) at 1000-2000 μm in thickness may provide between 50-100 dB shielding effectiveness in the band of 10 MHz-1 GHz.

While the above examples may provide decent EMI mitigation across a reasonably broad spectrum, their effectiveness may be dependent on thick shielding. Also, lower frequency protection (e.g., <10 MHz) may not meet current and/or future design constraints. The thickness of the shielding structure may (perhaps unexpectedly) open the semiconductor device to physical tampering (e.g., removing or damaging the shielding structure). A thick shielding structure may be vulnerable to attacks such as chemical etching. The thickness of the shielding may allow an attacker enough time to etch some or all of the shielding structure and then stop the etching without damaging the components/devices beneath. The attacker may thus gain access to the components/devices. The thickness of the shielding structure may also make it easier to physically remove the shielding structure (e.g., by prying etc.). A thinner shielding structure (especially if manufactured from hard-to-etch materials) may make tampering with the components/devices more difficult (by reducing the margin of error in etching the shielding structure), but also reduce the effectiveness against EMI. Thus, a shielding structure with an SE of 30 dB or more is needed, with a thickness small enough to resist tampering.

One solution may be to create a shielding structure including multiple, alternating layer. Some or all of the layers may be doped with a material such as a nano amorphous material in order to increase the SE of the shielding structure against one or more frequencies of electromagnetic radiation (EMR) and/or EMI. A maximum desired thickness of the shielding structure may be determined (e.g., by manufacturing constraints, design constraints, performance parameters, etc.) and provided to a computer system. Other inputs may also be provided such as desired SE frequency range, SE effectiveness threshold (e.g., 30 dB, 60 dB, etc.), and other such inputs. Then, the computing system may utilize the inputs to generate a model shielding structure with multiple, alternating layers. The model shielding structure may include any number of layers (e.g., 3, 9, 12, etc.) and include materials such as Al, CZT, NiFe, silicon (Si), a cobalt iron alloy (CoFe), and/or any other nano amorphous alloys.

Then, the computing system may simulate a semiconductor device including the model shielding structure during normal operation, under sniffing attack, etc. and measure the model shielding structure's SE. If the measured SE is above a certain threshold, then a design for a shielding structure may be generated by the computing system.

A shielding structure may then be generated according to the model shielding structure. A semiconductor device may be provided in a semiconductor processing chamber. A mask may be disposed on the semiconductor device configured to allow material to be deposited on the semiconductor device according to the design. Then, alternating layers may be deposited on the semiconductor device (e.g., via sputtering) in order to build the shielding structure to the maximum thickness. Because the number of layers, materials, and thickness of each individual layer is optimized by the computing system (and validated via simulation), the resulting shielding structure may be effective to the level required (e.g., to 30 dB) and thin-enough to resist tampering (e.g., via etching). Thus, the resulting shielding structure may provide increased EMI/EMR mitigation while also protecting the semiconductor device from tampering.

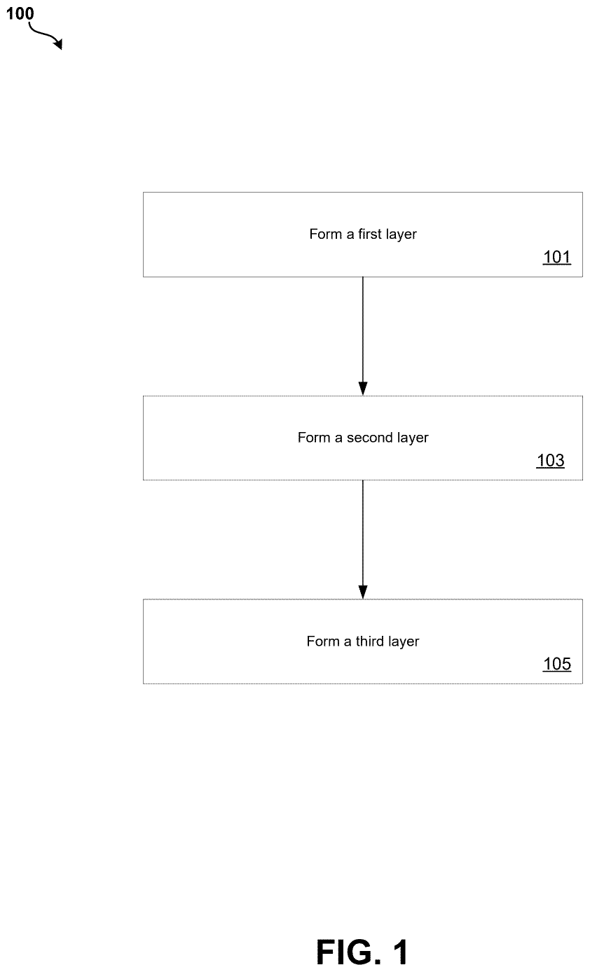

FIG. 1 illustrates a flowchart of a method 100 for manufacturing a tamper-resistant shielding structure, according to certain embodiments. The method 100 may be performed in a semiconductor processing chamber, configured to deposit one or more materials on a substrate, wafer, semiconductor device, etc. via one or more deposition techniques such chemical vapor deposition (CVD), plasma vapor deposition (PVD), sputtering, electrolysis, or any other suitable method.

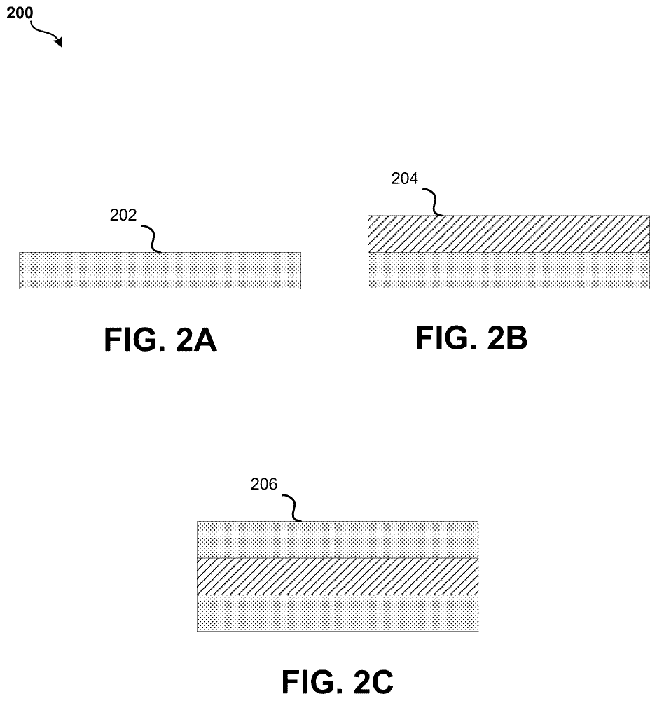

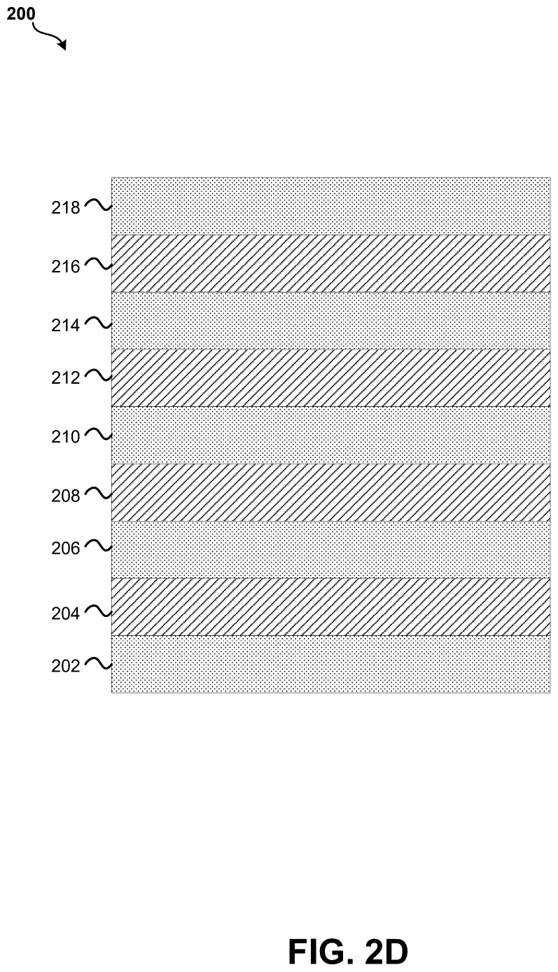

FIGS. 2A-2D illustrate a tamper resistant shielding structure 200, according to certain embodiments. FIGS. 2A-2D will be described in relation to FIG. 1. While FIGS. 2A-2D illustrate the shielding structure 200 in isolation, it should be understood that the shielding structure 200 may be formed on a semiconductor device (such as at a component level or on a package level) in the semiconductor processing chamber.

At step 102, the method may include forming, on a semiconductor device, a first layer 202 including a first material configured to prevent transmission of a first frequency of electromagnetic radiation (EMR) through at least the first layer, as seen in FIG. 2A. The first material may include Al, Cu, gold (Au), nickel (Ni), bronze, brass, stainless steel, and/or any other such material. The first layer 202 may exhibit SE against EMI and/or magnetic field interference, and may be dependent at least in part on the first material. For example, the first material may include Al. At a thickness of about 10 μm, the first layer 202 may then include a uniform plane source EMI SE of approximately −93 dB at low frequencies (e.g., ˜10 MHz), to a uniform place source EMI SE of approximately −93 dB at higher frequencies (e.g., ˜1 GHz). In other words, the first material may be selected at least in part based on a first frequency (or range of frequencies) to be shielded against. In some embodiments, the first material may include a doping material. For example, Al may be doped with silicon, iron, oxides thereof, and/or other such materials.

The first layer 202 may be formed by a deposition process such as sputtering, a evaporation-based process, or other such methods. The first layer 202 may be deposited to a thickness within in a range of about 250 nm to about 400 nm, inclusive. The first layer 202 may be deposited to a thickness within in a range of about 300 nm to about 350 nm, inclusive (e.g., 333 nm). The thickness of the first layer 202 may be determined via an optimization operation performed by a computing system and validated using a computer simulation. The thickness may be determined by the computing system at least in part to maximize and internal reflection of EMI between the first layer 202 and subsequent layers. The thickness may additionally or alternatively be determined at least in part to maximize and absorption of EMI by the first layer 202 and/or subsequent layers.

At step 104, the method 100 may include forming, on the first layer, a second layer 204 including a nano amorphous alloy configured to prevent transmission of a second frequency of EMR through at least the first layer and the second layer, as seen in FIG. 2B. The nano amorphous alloy may include Co, Fe, Ni, alloys thereof, and/or another such as Al, Si, Zr, tantalum (Ta), titanium (Ti), cadmium (Ca), magnesium (Mg), silver (Ag), and/or any other suitable material. The nano amorphous alloy may be selected in order to optimize electromagnetic properties of the second layer 204. For example, the second layer 204 may include CZT. Co may be selected as a ferromagnetic material in order to increase the SE against EMI and/or magnetic field interference. The Zr may be selected to provide increased refractory properties (e.g., to increase internal reflection within the shielding structure 200). Thus, the nano amorphous alloy may exhibit high magnetic permeability and high frequency stability.

The second layer 204 may be deposited to a thickness within in a range of about 250 nm to about 400 nm, inclusive. The second layer 204 may be deposited to a thickness within in a range of about 300 nm to about 350 nm, inclusive (e.g., 333 nm). The thickness of the second layer 204 may be determined via an optimization operation performed by a computing system and validated using a computer simulation. The thickness may be determined by the computing system at least in part to maximize and internal reflection of EMI between the second layer 204 and subsequent layers. The thickness may additionally or alternatively be determined at least in part to maximize and absorption of EMI by the second layer 204 and/or subsequent layers.

At step 106, the method 100 may include forming, on the second layer, a third layer 206 including a third material configured to prevent transmission of the EMR through at least the first layer 202, the second layer 204, and the third layer 206, wherein the first material, the nano amorphous material, and the third material are configured to maximize the internal reflection of the EMR between the first, second, and third layers. The third material may include Al, Cu, Au, No, bronze, brass, stainless steel, and/or any other such material. The third layer 206 may exhibit SE against EMI and/or magnetic field interference, and may be dependent at least in part on the third material. In some embodiments, the third layer 206 may be identical to the first layer. In other embodiments, the third layer 206 may be manufactured from a different material than the first layer.

The third layer 206 may be deposited to The first layer 202 may be deposited to a thickness within in a range of about 250 nm to about 400 nm, inclusive. The first layer 202 may be deposited to a thickness within in a range of about 300 nm to about 350 nm, inclusive (e.g., 333 nm). The thickness of the third layer 206 may be determined via the optimization operation performed by a computing system and validated using a computer simulation. The thickness may be determined by the computing system at least in part to maximize and internal reflection of EMI between the third layer 206 and subsequent layers. The thickness may additionally or alternatively be determined at least in part to maximize and absorption of EMI by the third layer 206 and/or subsequent layers.

In some embodiments, the steps 102-106 of the method 100 may be repeated any number of times to produce the shielding structure 200. As seen in FIG. 2D, the shielding structure 200 may include 9 alternating layers. Each adjacent layer may be made of a different material. For example, the layers 202, 206, 210, 214 and 216 may include the first material (collectively, “the aluminum layers”). The layers 204, 208, 210, and 212 may include a nano amorphous material (collectively, the “CZT layers”). The aluminum layers may include a thickness of between 250 nm to 350 nm, inclusive (e.g., 333 nm). The aluminum layers may be deposited via a sputtering process and provide absorption of EMI at a frequency range of between 1 MHz to 10 GHz, inclusive. The CZT layers may include a thickness identical to that of the aluminum layers (e.g., 333 nm) and be configured to reflect at least a portion of the EMI. In some embodiments, the CZT layers may include a different thickness than the aluminum layers. The CZT layers may be thinner than the aluminum layers.

The CZT layers may cause EMI to be reflected within the shielding structure 200. Because of the alternating layers of materials (e.g., Al and CZT), portions of EMI incident on the shielding structure 200 may be reflected between layers, reducing the amount of EMI transmitted to a subsequent layer. For example, a portion an EMI wave incident on the first layer 202 may pass through the first layer 202 to the second layer 204. As discussed above, the aluminum layers (e.g., the first layer 202) may at least partially absorb EMI. Thus, the portion of the EMI transmitted to the second layer 204 may be less than the EMI incident on the first layer 202. Because the second layer 204 may be manufactured from a ferromagnetic nano amorphous material (e.g., CZT), some of the transmitted portion of the EMI wave may be reflected back to the first layer 202 such that the first layer 202 absorbs even more of the EMI wave. This process of internal reflection and absorption may be repeated through each layer of the shielding structure 200. If any of the EMI wave passes through all the layers of the shielding structure 200, the resulting wave may be drastically attenuated.

Furthermore, because the shielding structure 200 may be optimized for a particular application in terms of layer thickness, material, overall thickness, etc., the shielding structure 200 may be very thin (e.g., 2 μm, 3 μm, 4 μm, etc.) while still providing an SE within a range of 20 dB to 80 dB (e.g., 60 dB). Additionally, the materials of the shieling structure 200 may be chosen such that the shielding structure 200 is tamper-resistant. As described above, the materials for the layers 202-216 may be selected (at least in part) for certain physical properties. Al and CZT, for example, may be chosen at least in part due the difficulty in etching one or both materials. Thus, an attacker attempting to access the semiconductor device underneath the shielding structure 200 may destroy the semiconductor device when etching the shielding structure 200 (due to the thinness of the shielding structure 200). For similar reasons, other techniques such as ablation, heat-based attacks, etc. may also fail due to the thinness of the shielding structure 200.

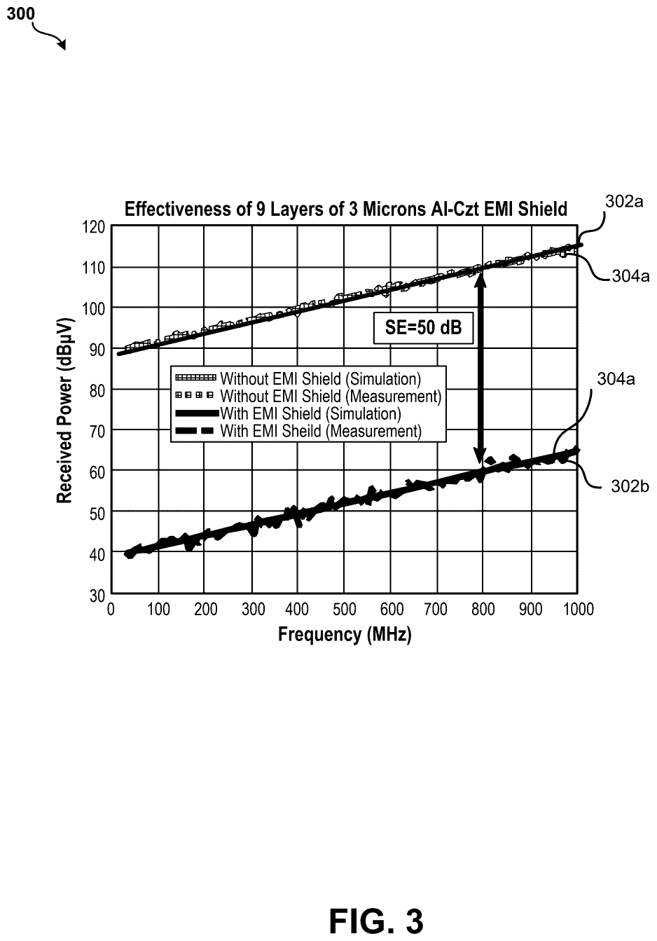

FIG. 3 illustrates a graph 300 of the shield effectiveness of a 9-layer shielding structure, according to certain embodiments. The 9-layer shielding structure may be similar to the shielding structure 200 described in FIG. 2D. Thus, the 9-layer shielding structure may include alternating layers of a first material and a nano amorphous material. Specifically, the graph 300 may illustrate the SE of a 3 μm, 9 layer Al and CZT shielding structure.

The thickness of each of the layers may be optimized using the techniques and systems described herein. For example, the thickness of each of the layers may be optimized utilizing inputs provided to a computing system such as the overall thickness, performance parameters, applications, etc. The optimization problem may be described as:

AdB=−8.69(t1δ1+t2δ2+ . . . +tnδn) (1)

RLdB=−20 log 10((Zs1+Zw)·(Zs1+Zs2) . . . (Zsn+Zw)2Zw2Zs1 . . . 2Zsn) (2)

A+RL>SEtarget (3)

t1+t2+t3 . . . +tn=tmax (4)

tmin≤ti≤tmax (5)

SE=A+RL (6)

Where: A=the absorption loss in dB; ti=the thickness of layer ith in m; tmin=minimum layer thickness in m; tmax=maximum layer thickness in m; δi=the thickness of layer ith in m; RL=the absorption loss in dB; Zw=wave impedance in Ω, Zsi=shield impedance of layer ith in Ω; and SE=the targeted shielding effectiveness in dB. The optimization problem may be tuned or adjusted based on an intended use, such as whether the shielding structure is to be used as component-level shielding structure or a package level shielding structure.

After determining the various characteristics of the shielding structure using the optimization problem, the computing system may generate a model 9-layer shielding structure and simulate the operation of a semiconductor device including the model. Additionally, the computing system may simulate the operation of the semiconductor device without the shielding structure. The unshielded simulation is shown as line 302a, and the shielded simulation is shown as line 302b.

The computing system may generate a manufacturing plan according to the model. Then, the shielding structure may be manufactured (e.g., utilizing the method 100) on a semiconductor device. Then, the semiconductor device may be tested in normal operation to determine the SE of the shielding structure. The results of the tested devices may be illustrates as lines 304a (unshielded) and 304b (shielded).

As seen in the graph 300, the line 302a shows that the unshielded simulation indicates that the semiconductor device may experience approximately 90 dBμV at 50 MHzm and approximately 115 90 dBμV at 1 GHz. The line 304a shows that the model is largely validated, indicating that testing of a physical device without shielding also experiences approximately 90 dBμV at 50 MHzm. The line 302b shows that the shielded simulation indicates that the semiconductor device may experience approximately 40 dBμV at 50 MHzm and approximately 65 dBμV at 1 GHz. The line 304b confirms these predictions. Additionally, the lines 302a-b and 304a-b may be approximately linear. Thus, the SE of the 9-layer AL-CZT shielding structure may provide about 50 dB at all frequencies between about 50 MHz to about 1 GHZ.

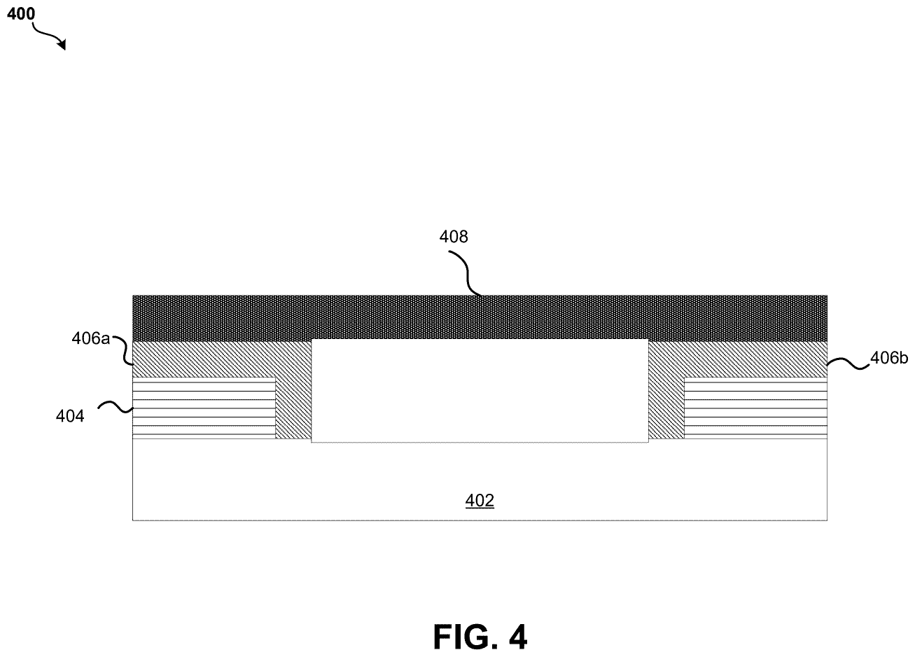

FIG. 4 illustrates a semiconductor device 400 with component-level shielding structures 406a-b, according to certain embodiments. The semiconductor device 400 may include a substrate 402, a device layer 404, the shielding structures 406a-b, and a second layer 408. The semiconductor device 400 may be manufactured in a semiconductor processing chamber configured to deposit material via processes such as CVD, PVD, sputtering etc. The semiconductor device 400 may be a semiconductor package, including one or more various components. After the device layer 404 is deposited on the substrate 402, the shielding structures 406a-b may be deposited over some or all the device layer 404 (e.g., via the process 100). Although the shielding structures 406a-b are shown as a single structure, it should be understood that the shielding structures 406a-b may include two or more layers (e.g., 9 layers) of alternating materials such as Al and CZT. The total thickness of the shielding structures 406a-b over the device layer 404 may be 2 μm, 3 μm, 4 μm, etc. Thus, the shielding structures 406a-b may not only provide SE against EMI in a range of 10 MHz-1 GHZ, but also provide tamper resistance due to the thinness of the shielding structures 406a-b. Then, the dielectric layer 408 (or other layers such as a redistribution layer (RDL), a second device layer, vias, etc.) may be deposited over the shielding structures 406a-b to further manufacture the semiconductor device 400.

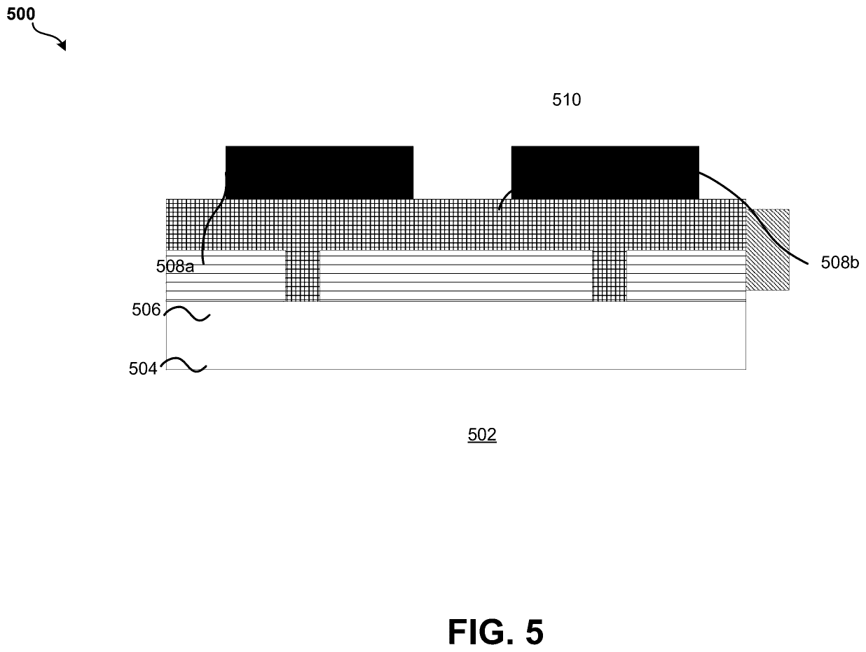

FIG. 5 illustrates a semiconductor device 500 with a package-level shielding structure 510, according to certain embodiments. The semiconductor device 500 may include a substrate 502, a PDN 504, an RDL 506, components 508a-b, and the shielding structure 510. The semiconductor device 500 may be manufactured in a semiconductor processing chamber configured to deposit material via processes such as CVD, PVD, sputtering etc. The semiconductor device 500 may be a semiconductor package, including one or more various components. The various layers and components of the semiconductor device 500 may be manufactured with or without additional shielding. Then, the shielding structure 510 may be deposited over some or all of the semiconductor device 500, providing package-level shielding. Although the shielding structure 510 is shown as a single structure, it should be understood that the shielding structure 510 may include two or more layers (e.g., 9 layers) of alternating materials such as Al and CZT. The total thickness of the shielding structure 410 may be 2 μm, 3 μm, 4 μm, etc. Thus, the shielding structure 510 not only provide SE against EMI in a range of 10 MHz-1 GHz, but also provide tamper resistance due to the thinness of the shielding structure 410.

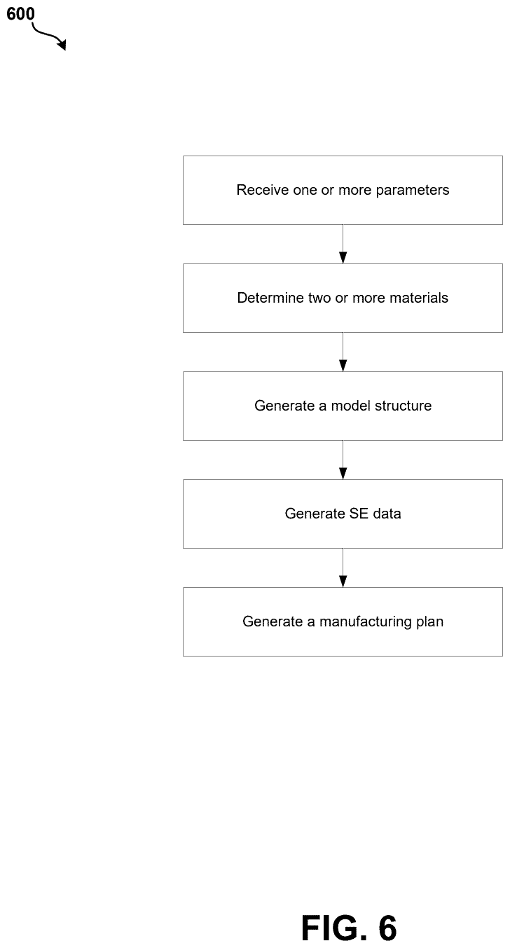

FIG. 6 illustrates a flowchart of a method 600 for generating a manufacturing plan for a shielding structure, according to certain embodiments. The method 600 may be performed by a computing system including one or more physical or virtual machines. The computing system may include one or more processors and a computer-readable medium that includes instructions according to the method 600. Some of the steps of the method 600 may be performed in an order different than is described here, or may be combined with other steps. In some embodiments, some steps may be skipped altogether.

At step 602, the method 600 may include receiving, by a computing system, one or more parameters defining shielding effectiveness (SE) of the EMR shielding structure, manufacturing parameters, or some combination thereof. The one or more parameters may be defined as variables in an optimization problem as described in relation to FIG. 3. The one or more parameters may include manufacturing tolerances, a total thickness, a frequency range, an SE value (e.g., 50 dB), and other such parameters.

At step 604, the method 600 may include determining, by the computing system, two or more materials according to the one or more parameters. The materials may include various metals, alloys, polymers, etc. For example, one material may be a material such as Si, Al, etc. Another material may include a nano amorphous material such as CZT. The materials may be determined based on physical properties (e.g., heat resistance, case of etching, etc.). The materials may additionally or alternatively be determined on electromagnetic properties such as permeability, conductivity, etc. The materials may also be chosen based on how the materials may interact (e.g., internal reflection, absorption of EMI, etc.).

At step 606, the method 600 may include generating, by the computing system, a model EMR shielding structure comprising the two or more materials and according to the one or more parameters, wherein the model EMR shielding structure includes two or more layers, wherein adjacent layers comprise different materials of the two or more materials. The model may also include a thickness of each of the layers (e.g., 250 nm, 333 nm, etc.).

At step 608, the method 600 may include generating, by the computing system, SE data by simulating the operation of a semiconductor device including the model EMR shielding structure. The SE data may be plotted on a graph as is shown in FIG. 3. The SE data may be validated against real world testing.

If the if the SE data is within the one or more parameters, at step 610, the method 600 may include generating, by the computing system, a manufacturing plan for the EMR shielding structure indicating the two or more layers and the two or more materials of the model shielding structure.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user or may be done automatically by a computer system without human intervention where any determinations are made by a processor. Furthermore, some embodiments of each of the methods described herein may be implemented as a set of instructions stored on a tangible, non-transitory storage medium to form a tangible software product.

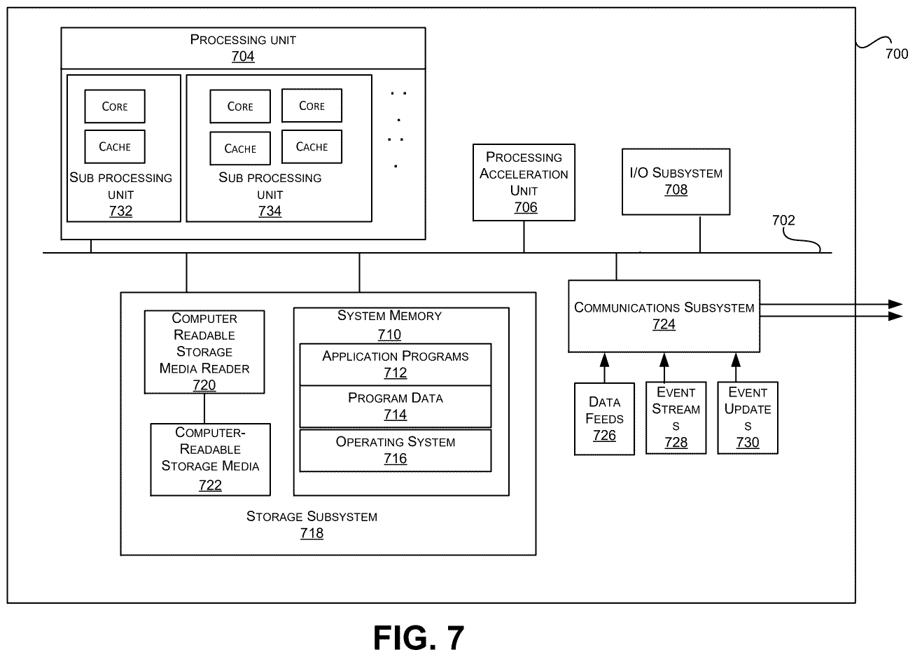

FIG. 7 illustrates an exemplary computer system 700, in which various embodiments may be implemented. The system 700 may be used to implement any of the computer systems described above. As shown in the figure, computer system 700 includes a processing unit 704 that communicates with a number of peripheral subsystems via a bus subsystem 702. These peripheral subsystems may include a processing acceleration unit 706, an I/O subsystem 708, a storage subsystem 718 and a communications subsystem 724. Storage subsystem 718 includes tangible computer-readable storage media 722 and a system memory 710.

Bus subsystem 702 provides a mechanism for letting the various components and subsystems of computer system 700 communicate with each other as intended. Although bus subsystem 702 is shown schematically as a single bus, alternative embodiments of the bus subsystem may utilize multiple buses. Bus subsystem 702 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 704, which can be implemented as one or more integrated circuits (e.g., a conventional microprocessor or microcontroller), controls the operation of computer system 700. One or more processors may be included in processing unit 704. These processors may include single core or multicore processors. In certain embodiments, processing unit 704 may be implemented as one or more independent processing units 732 and/or 734 with single or multicore processors included in each processing unit. In other embodiments, processing unit 704 may also be implemented as a quad-core processing unit formed by integrating two dual-core processors into a single chip.

In various embodiments, processing unit 704 can execute a variety of programs in response to program code and can maintain multiple concurrently executing programs or processes. At any given time, some or all of the program code to be executed can be resident in processor(s) 704 and/or in storage subsystem 718. Through suitable programming, processor(s) 704 can provide various functionalities described above. Computer system 700 may additionally include a processing acceleration unit 706, which can include a digital signal processor (DSP), a special-purpose processor, and/or the like.

I/O subsystem 708 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices that enables users to control and interact with an input device through a natural user interface using gestures and spoken commands. Additionally, user interface input devices may include voice recognition sensing devices that enable users to interact with voice recognition systems through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader, 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 700 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 700 may comprise a storage subsystem 718 that comprises software elements, shown as being currently located within a system memory 710. System memory 710 may store program instructions that are loadable and executable on processing unit 704, as well as data generated during the execution of these programs.

Depending on the configuration and type of computer system 700, system memory 710 may be volatile (such as random access memory (RAM)) and/or non-volatile (such as read-only memory (ROM), flash memory, etc.). The RAM typically contains data and/or program modules that are immediately accessible to and/or presently being operated and executed by processing unit 704. In some implementations, system memory 710 may include multiple different types of memory, such as static random access memory (SRAM) or dynamic random access memory (DRAM). In some implementations, a basic input/output system (BIOS), containing the basic routines that help to transfer information between elements within computer system 700, such as during start-up, may typically be stored in the ROM. By way of example, and not limitation, system memory 710 also illustrates application programs 712, which may include client applications, Web browsers, mid-tier applications, relational database management systems (RDBMS), etc., program data 714, and an operating system 716.

Storage subsystem 718 may also provide a tangible computer-readable storage medium for storing the basic programming and data constructs that provide the functionality of some embodiments. Software (programs, code modules, instructions) that when executed by a processor provide the functionality described above may be stored in storage subsystem 718. These software modules or instructions may be executed by processing unit 704. Storage subsystem 718 may also provide a repository for storing data used in accordance with some embodiments.

Storage subsystem 700 may also include a computer-readable storage media reader 720 that can further be connected to computer-readable storage media 722. Together and, optionally, in combination with system memory 710, computer-readable storage media 722 may comprehensively represent remote, local, fixed, and/or removable storage devices plus storage media for temporarily and/or more permanently containing, storing, transmitting, and retrieving computer-readable information.

Computer-readable storage media 722 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 700.

By way of example, computer-readable storage media 722 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD or other optical media. Computer-readable storage media 722 may include, but is not limited to, flash memory cards, universal serial bus (USB) flash drives, secure digital (SD) cards, DVD disks, digital video tape, and the like. Computer-readable storage media 722 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 700.

Communications subsystem 724 provides an interface to other computer systems and networks. Communications subsystem 724 serves as an interface for receiving data from and transmitting data to other systems from computer system 700. For example, communications subsystem 724 may enable computer system 700 to connect to one or more devices via the Internet. In some embodiments communications subsystem 724 can include radio frequency (RF) transceiver components for accessing wireless voice and/or data networks (e.g., using cellular telephone technology, advanced data network technology, such as 3G, 4G, 7G, or EDGE (enhanced data rates for global evolution), WiFi (IEEE 802.7 family standards, or other mobile communication technologies, or any combination thereof), global positioning system (GPS) receiver components, and/or other components. In some embodiments communications subsystem 724 can provide wired network connectivity (e.g., Ethernet) in addition to or instead of a wireless interface.

In some embodiments, communications subsystem 724 may also receive input communication in the form of structured and/or unstructured data feeds 726, event streams 728, event updates 730, and the like on behalf of one or more users who may use computer system 700.

By way of example, communications subsystem 724 may be configured to receive data feeds 726 in real-time from users of social networks and/or other communication services, web feeds such as Rich Site Summary (RSS) feeds, and/or real-time updates from one or more third party information sources.

Additionally, communications subsystem 724 may also be configured to receive data in the form of continuous data streams, which may include event streams 728 of real-time events and/or event updates 730, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 724 may also be configured to output the structured and/or unstructured data feeds 726, event streams 728, event updates 730, and the like to one or more databases that may be in communication with one or more streaming data source computers coupled to computer system 700.

Due to the ever-changing nature of computers and networks, the description of computer system 700 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

What is claimed is:

1. A method of forming a shielding structure, comprising:
forming, on a semiconductor device, a first layer comprising a first material configured to prevent transmission of electromagnetic radiation (EMR) through at least the first layer;
forming, on the first layer, a second layer comprising a nano amorphous material configured to prevent transmission EMR through at least the first layer and the second layer; and
forming, on the second layer, a third layer comprising a third material configured to prevent transmission of EMR through at least the first layer, the second layer, and the third layer, wherein the first material, the nano amorphous material, and the third material are configured to maximize the internal reflection of the EMR between the first, second, and third layers.

2. The method of claim 1, wherein a total thickness of the first, second, and third layers is within a range of 3.5 micrometers and 2.5 micrometers, inclusive.

3. The method of claim 1, wherein the first, second, and third layers are formed via a sputtering process.

4. The method of claim 1, wherein the first and third layers comprise aluminum.

5. The method of claim 1, wherein the second layer comprises cadmium zinc telluride (CZT).

6. The method of claim 1, wherein at least one of the first layer, the second layer, or the third layer comprises a nano amorphous alloy.

7. The method of claim 1, wherein the semiconductor device is a component of a semiconductor package.

8. The method of claim 1, wherein the shielding structure is configured to reduce the transmission of the first frequency, the second frequency, and the third frequency by 40 dB to 80 dB, inclusive.

9. The method of claim 1, wherein the first layer is formed to a thickness of between 250 nm and 400 nm, inclusive.

10. A semiconductor package, comprising:
a substrate;
a semiconductor device disposed on the substrate;
an interconnect layer electrically connected to the semiconductor device; and
an electromagnetic radiation (EMR) shielding structure disposed on the semiconductor device, the interconnect layer, or some combination thereof configured to shield the semiconductor device from tampering, the EMR shielding structure comprising:
a first aluminum layer;
a czt layer; and
a second aluminum layer.

11. The semiconductor package of claim 10, wherein the EMR shielding structure has a thickness in a range of 2.5 to 3.5 micrometers, inclusive.

12. The semiconductor package of claim 10, wherein the EMR shielding structure is configured to shield EMR frequencies in a range of 50 MHz to 2000 MHz, inclusive.

13. The semiconductor package of claim 10, wherein the EMR shielding structure comprises a set of aluminum layers and a set of CZT layers, and the total number of layers is 9.

14. The semiconductor package of claim 10, wherein the CZT layer comprises at least one of tantalum, zirconium, or some combination thereof.

15. The semiconductor package of claim 10, wherein the aluminum layer comprises at least one of silicon, iron, or some combination thereof.

16. The semiconductor package of claim 10, wherein the shielding structure comprises a cobalt iron alloy.

17. A method of generating a manufacturing plan for a shielding structure, the method comprising:
receiving, by a computing system, one or more parameters defining shielding effectiveness (SE) of the shielding structure, manufacturing parameters, or some combination thereof;
determining, by the computing system, two or more materials according to the one or more parameters;
generating, by the computing system, a model shielding structure comprising the two or more materials and according to the one or more parameters, wherein the model shielding structure comprises two or more layers, wherein adjacent layers comprise different materials of the two or more materials;
generating, by the computing system, SE data by simulating the operation of a semiconductor device comprising the model shielding structure; and
if the SE data is within the one or more parameters:
generating, by the computing system, a manufacturing plan for the EMR shielding structure indicating the two or more layers and the two or more materials of the model shielding structure.

18. The method of claim 17, wherein at least one of the two or more materials comprises a nano amorphous alloy.

19. The method of claim 17, wherein the EMR shielding structure has a thickness in a range of 2.5 to 3.5 micrometers, inclusive.

20. The method of claim 17, wherein the model EMR shielding structure is simulated on a semiconductor package.
